(19) United States
(12) Patent Application Publication
(10) Pub. No.: US 2015/0085335 A1
(43) Pub. Date: Mar. 26, 2015

(54) CHIROPTICAL SWITCHES

(71) Applicants: Jas Pal S. Badyal, Wolsingham (GB); Wayne Christopher Edward Schofield, Durham (GB)

(72) Inventors: Jas Pal S. Badyal, Wolsingham (GB); Wayne Christopher Edward Schofield, Durham (GB)

(21) Appl. No.: 14/237,471

(22) PCT Filed: Aug. 8, 2012
(86) PCT No.: PCT/GB2012/051925

§ 371 Date: Oct. 23, 2014

(30) Foreign Application Priority Data
Aug. 8, 2011 (GB) 1113610.8

(51) Int. Cl. G02F 1/00; C23C 16/50; C23C 16/515; G02F 1/01

(52) U.S. Cl. CPC G02F 1/0063; G02F 1/0126; C23C 16/50; C23C 16/515
USPC 359/241; 427/569

(57) ABSTRACT

A method for fabricating surface tethered chiroptical switches that constitute polymer chains bearing chromophoric functional groups with the ability to undergo geometrical re-alignment upon irradiation with polarized light to yield a measurable chiral anisotropy, by formation of a layer on a substrate by deposition of a compound containing at least one functional group and attachment of chiro-optical molecule to said functional group.

The present invention relates to chiroptical switches comprising chiro-optical molecules tethered to a layer deposited on a substrate and also to a method of fabricating the chiroptical switches.

### BACKGROUND

Chiroptical switches which undergo a reversible change in supramolecular chirality upon external stimulus are of great interest for optical devices [1], data storage [2], and nanoscale machinery [3]. Compared to molecular switches [4],[5], these systems are attractive because of their non-covalent modus operandi which make them far easier to control [6],[7]. Typically, they constitute polymer chains bearing chromophoric functional groups with the ability to undergo (chromophore) geometrical re-alignment upon irradiation with polarized light to yield a measurable chiral anisotropy (i.e. Weigert effect)
[8], [9], [10], [11].

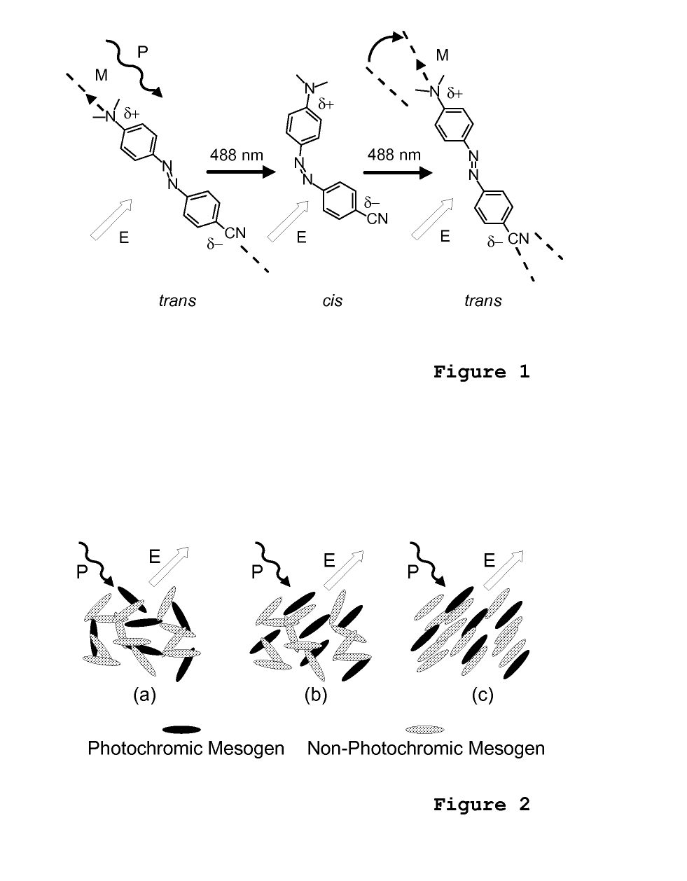

Rod-like (i.e. mesogen) para-substituted azobenzene chromophore derivatives with electron-donor or electron-acceptor substituents such as amine, cyano or nitro groups [12] are amongst the most promising building blocks for chiroptical switches stemming from the in-built reversible trans-cis-trans photoisomerization contained within the azobenzene chromophore
[13] which is capable of inducing large changes in chiroptical behaviour of the parent macromolecule backbone on the supramolecular scale as a direct response to alteration of the “handedness” of impinging circularly polarized light (i.e. supramolecular enantiomeric toggling) [12]. Effectively, the mechanism governing para-substituted azobenzene chromophore chiroptical behaviour involves two processes; firstly there are repeated photoinduced molecular trans-cis-trans isomerization cycles at a single wavelength (i.e. absorption maxima for both the trans-cis and the cis-trans azobenzene photoisomerization processes are superimposed), FIG. 1. The trans-isomer is more stable than the cis-isomer, thus causing any photo-generated cis-isomer species to revert back to trans-isomer on the picosecond timescale [13]. Secondly, there is stepped alignment of the chromophoric azobenzene groups towards a direction parallel to the electric field vector (perpendicular to the direction of the polarized light) [12], [69]; this arises due to the para-substituted azobenzene group's strong dipole moment (i.e. its inherent electric field) gradually reorienting its axis towards a parallel alignment [14] with the polarized light source electric field (regardless of whether cis- or trans-configuration), FIG. 1. Eventually, after a sufficient number of trans-cis-trans photoisomerization cycles (movements), the azobenzene dipole moment becomes aligned parallel to the electric field (perpendicular to the light polarization) and then becomes irresponsive towards further light exposure [12] (i.e. a saturation level is reached). Effectively, the rapid azobenzene chromophore trans-cis-trans photoisomerizations produce a series of chromophore (and therefore associated tethering polymer backbone) realignment motions. The rates and extent of chromophoric movement strongly depend upon polymer matrix viscosity and there being sufficient local volume to allow chromophore dipole moment transitions to take place within the polymer matrix (known as the occupied volume [12]). Indeed, the dipole moment occupied volume of the cis-azobenzene isomer is larger than that of the trans-azobenzene isomer [15] and therefore the photoconversion from the cis-isomer to trans-isomer is accompanied by volumetric changes [16]. The overall extent to which azobenzene chromophore alignment/ordering takes place is dependent upon both the duration and intensity of light exposure [13].

Polarized light photoisomerization of polymer tethered azobenzene chromophore groups can provide two types of polymer backbone motion: at the nanometer (polymer domain) level, and on the micrometer (macroscopic) scale. In the former case, realignment motion of the azobenzene chromophores perpendicular to the polarized light direction gives rise to the formation of mesogen organized nematic layers akin to those found in liquid crystalline films [17], crystalline domains [18], Langmuir-Blodgett layers [19], or monomolecular films [20], FIG. 2. This produces an overall competition between two inherent driving forces for polymer ordering: on the one hand there is the liquid crystalline realignment perpendicular to the direction of the polarized light [21] (which is governed by polymer flexibility i.e. polymer viscosity and azobenzene chromophore occupied volume); whilst conversely, any pre-light exposure order contained within the system (due to intrinsic polymer matrix ordering) will oppose such new liquid crystalline alignment [22]. Given the high trans-cis-trans photoisomerization quantum yields for azobenzenes, there exists a strong impetus for the mesogen driven reorientation of whole liquid crystalline nematic layers towards a direction perpendicular to the polarized light [23]. Furthermore, these motions occur on the length scales of liquid crystalline layers or within crystalline domains (whose sizes are of the order of nanometers), which means that the overall movement of material exceeds the underpinning chromophoric motion. Such behaviour leads to the concurrent alignment of the adjacent non-chromophoric polymer backbone to which the chromophore groups are attached (i.e. cooperative photo-reorientation [24]), FIG. 2. On the micrometer (macroscopic) scale, this motion involves massive movement of the polymer material as a further extension of the cooperative photo-reorientation, where the driving force consists of pressure gradients created by interfering light and unequal isomerization patterns [25]. Such macroscopic motion can produce visible patterns on film surfaces with depth and spacing reaching the micrometer scale (as often used for holographic gratings) [26].

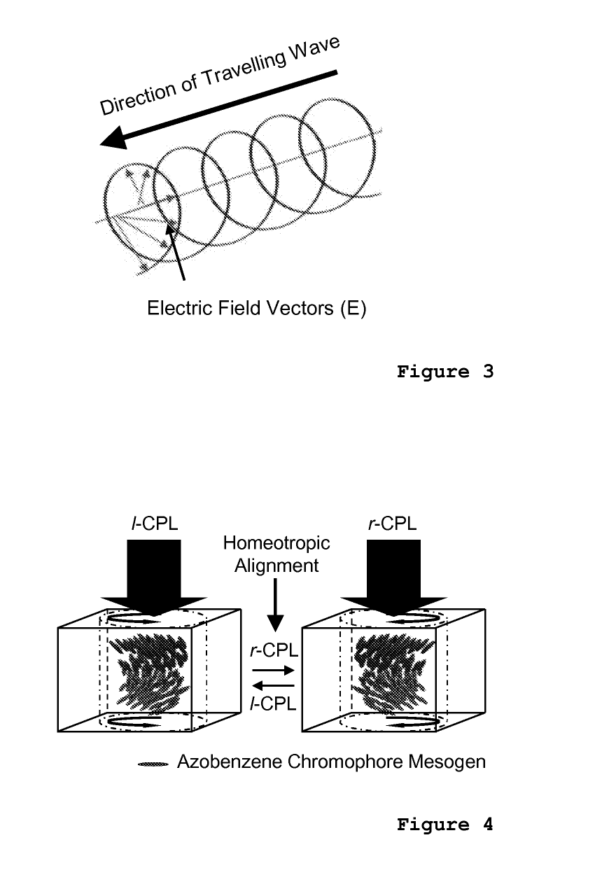

For the case of circularly polarized light incident upon polymer nanolayers containing azobenzene chromophore side groups, the azobenzene chromophore mesogens adopt a supramolecular helical orientation giving rise to measurable supramolecular geometrical chirality by circular dichroism spectroscopy [27] (i.e. the Weigert effect). Polymers containing azobenzene chromophoric side groups have previously been reported to display a series of mesogen developed nematic liquid crystalline smectic C* layers
[28] attributable to a circular helical twisting of the azobenzene chromophore mesogens perpendicular to the polarized light direction (where the circularly polarized light traces a helix through the film layer, FIG. 3). A finite twist angle arises between adjacent azobenzene chromophore mesogens under the influence of the helical electric field associated with the circularly polarized light source leading to their asymmetric packing to produce longer-range chiral order [29]. The direction of the helix (clockwise or anticlockwise) can be controlled and realigned by switching the “handedness” of the incident light
[30] (from right to left circularly polarized light), i.e. supramolecular enantiomeric toggling, FIG. 4.

Three different approaches are currently known for preparing surface localised azobenzene chiroptical supramolecular polymer switches. Firstly there is the synthesis and polymerization of monomers containing the azobenzene photochromic side-group, followed by their physisorption onto the surface [28],[31]. Alternatively, surface physisorbed polymers are derivatized with photochromic azobenzene molecules [2],[32]. Both of these physisorption methods require multi-step wet chemical reactions which are applicable to only a limited number of substrates (e.g. silicon [33],[34],[35] or silica [36],[37]), and remain inherently susceptible to solvent removal. The third approach entails direct covalent attachment onto gold surfaces via self-assembled monolayers (SAMs) of thiol-containing photochromic azobenzene molecules [38],[39]. However, these systems are only able to provide sufficient “free volume” to allow the photoswitching of azobenzene to occur [40] when it is sufficiently decoupled [41] from the substrate, and furthermore the gold-thiol linkage suffers from long term stability issues
[42]. Overall, such drawbacks limit both availability and widespread application of fully functional chiroptical surfaces
[43],[44].

A first aspect of the present invention provides a method for fabricating surface tethered chiroptical switches, comprising:
(a) formation of a layer on a substrate by deposition of a compound containing at least one functional group;
(b) attachment of a chiro-optical molecule to said functional group.

The chiroptical switch may, in an embodiment of the invention, constitute polymer chains bearing chromophoric functional groups with the ability to undergo (chromophore) geometrical re-alignment upon irradiation with polarized light to yield a measurable chiral anisotropy.

The switch may undergo a reversible change in supramolecular chirality upon an external stimulus.

The functional group may comprise an epoxide functional group. The functional group may comprise an aldehyde group, a carboxylic acid group, or an anhydride group.

The layer may be polymeric, i.e. comprise one or more polymer chains.

Monomers for formation of the layer may be selected from the group of styrenes, acrylates, methacrylates, and acrylonitrile, for example glycidyl methacrylate.

The layer may be formed using glycidyl methacrylate.

The layer may comprise a nanolayer, for example the thickness of the layer may be 100-200 nm.

The layer may be patterned. Alternatively or additionally the chiro-optical molecule may be spatially applied onto the deposited layer. Spatial application may include but is not limited to printing, spraying, inkjet printing, screen printing, offset lithography, photocopying, flexography, or gravure process.

The chiro-optical molecule may comprise at least one chiral centre. In one embodiment, the chiro-optical molecule comprises two chiral centres. The chiro-optical molecule may comprise multiple chiral centres. The chiro-optical molecule may comprise at least one constrained chiral centre.

The functional group, e.g. the epoxide group, may be derivatised by the chiro-optical molecule. In one embodiment, the epoxide group is derivatised by an aminolysis reaction.

The chiro-optical molecule may comprise an azobenzene chromophore. The chiro-optical molecule may comprise a para-substituted azobenzene chromophore derivative with electron-donor or electron-acceptor substituents such as amine, cyano or nitro groups. The chiro-optical molecule may comprise a pyrrolidine functional group. In one embodiment, the chiro-optical molecule comprises (S)-3-methyl-3-amino-1(4′-cyano-4-azobenzene)pyrrolidine.

As an alternative to the azobenzene chromophore, an isocyanate or stilbene chromophore may be used.

The layer may be deposited by a method selected from the group of surface initiated grafting, grafting to the surface, grafting from the surface, plasma polymerization, plasma-initiated grafting, thermal chemical vapour deposition, initiated chemical vapour deposition (iCVD), photodeposition, ion-assisted deposition, electron beam polymerization, gamma-ray polymerization, and target sputtering.

The compound containing the functional group may be used for deposition in the absence of any other material.

Additional material may be used in combination with the compound containing the functional group during deposition of the layer. Said additional material may be inert and may not be incorporated into the deposition later. Alternatively, said additional material may be incorporated into the deposited layer.

In one embodiment deposition comprises plasma deposition. The plasma may be pulsed. In one embodiment, the duty cycle of the plasma is on for 20 μm:off for 20 ms. The peak power of the plasma may be between 30 W and 50 W.

This method is suitable for any substrate. The substrate may be selected from, but not limited to, the group of glass, metal, polymer, silicon, textiles, ceramics, semiconductors, or cellulosic materials.

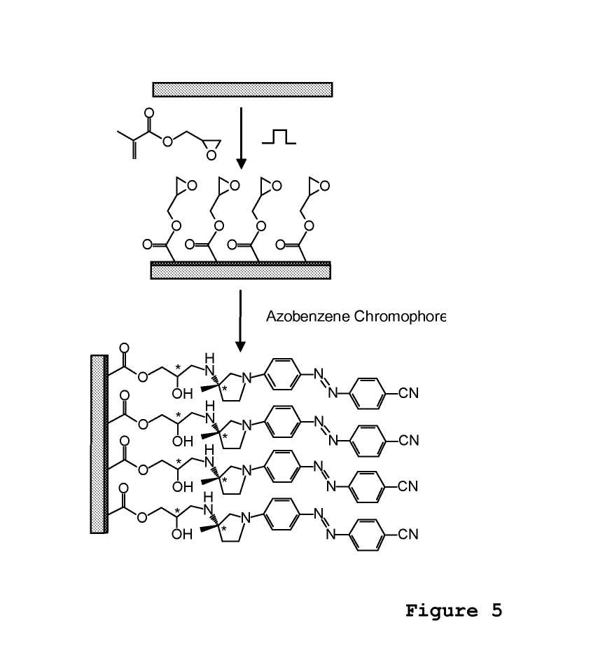

The present invention is a straightforward two-step substrate-independent methodology for fabricating surface tethered chiroptical switches. This may preferably entail pulsed plasmachemical deposition of structurally well-defined poly(glycidyl methacrylate) ultrathin films [45], followed by the aminolysis reaction of the polymer epoxide side groups with the primary amine of the chiroptical molecule (S)-3-methyl-3-amino-1-(4′-cyano-4-azobenzene)pyrrolidine, FIG. 5. Pulsed plasmachemical deposition is a straightforward and effective approach for functionalizing solid surfaces (single-step, solventless, and substrate independent) comprising the generation of active sites (predominantly radicals) at the surface and within the electrical discharge during the duty cycle on-period (microseconds), followed by conventional polymerization reaction pathways proceeding during each extinction period (milliseconds) [46]. The high level of structural retention attained has been verified by time-of-flight secondary ion mass spectrometry (ToF-SIMS) to be comparable to conventional solution based polymerization [45],
[46A]. Preprogramming the pulsed plasma duty cycle enables the surface density of functional groups to be tailored. Well-defined robust functional nanolayers containing anhydride [46], carboxylic acid [47], cyano [48], epoxide [45], hydroxyl [49], furfuryl [50], thiol [51], amine [52], perfluoroalkyl [53], perfluoromethylene [54], and trifluoromethyl [55] groups have been successfully prepared in the past by this methodology. Effectively this approach offers scope for the fabrication of surface tethered supramolecular chiroptical switches onto a plethora of solid surfaces and substrate geometries.

Plasma polymers are typically generated by subjecting a coating forming precursor to an ionising electric field under low pressure conditions. Deposition occurs when excited species generated by the action of the electric field upon the precursor (radicals, ions, excited molecules etc) polymerise in the gas phase and react with the substrate surface to form a growing polymer film.

Precise conditions under which pulsed plasma deposition for the coatings takes place is an effective manner will vary depending upon factors such as the nature of the monomer, the substrate, the size and architecture of the plasma deposition chamber etc and will be determined using routine methods and/or the techniques.

Suitable plasmas for use in the method described herein include non-equilibrium plasmas such as those generated by radio frequencies (RF), microwaves or direct current (DC). They may operate at atmospheric or sub-atmospheric pressures as are known in the art. In particular however, they are generated by radio frequencies (RF).

Various forms of equipment may be used to generate gaseous plasmas. Generally these comprise containers or plasma chambers in which plasmas may be generated. Particular examples of such equipment are described for instance in WO2005/089961 and WO02/28548, but many other conventional plasma generating apparatus are available.

In general, the item to be treated is placed within a plasma chamber together with the material to be deposited in gaseous state, a glow discharge is ignited within the chamber and a suitable voltage is applied.

The gas used within the plasma may comprise a vapour of the monomeric compound alone, but it may be combined with a carrier gas, in particular, an inert gas such as helium or argon. In particular helium is a preferred carrier gas as this can minimise fragmentation of the monomer.

When used as a mixture, the relative amount of the monomer vapour to carrier gas is suitably determined in accordance with procedures which are conventional in the art. The amount of monomer added will depend to some extent on the nature of the particular monomer being used, the nature of the substrate being treated, the size of the plasma chamber etc. Generally, in the case of conventional chambers, monomer is delivered in an amount of from 50-250 mg/min, for example at a rate of from 100-150 mg/min. Carrier gas such as helium is suitably administered at a constant rate for example at a rate of from 5-90, for example from 15-30 sccm. In some instances, the ratio of monomer to carrier gas will be in the range of from 100:1 to 1:100, for instance in the range of from 10:1 to 1:100, and in particular about 1:1 to 1:10. The precise ratio selected will be so as to ensure that the flow rate required by the process is achieved.

In some cases, a preliminary continuous power plasma may be struck for example for from 2-10 minutes for instance for about 4 minutes, within the chamber. This may act as a surface pre-treatment step, ensuring that the monomer attaches itself readily to the surface, so that as polymerisation occurs, the coating “grows” on the surface. The pre-treatment step may be conducted before monomer is introduced into the chamber, in the presence of only the inert gas.

A glow discharge is suitably ignited by applying a high frequency voltage, for example at 13.56 MHz. This is suitably applied using electrodes, which may be internal or external to the chamber, but in the case of the larger chambers are internal.

Suitably the gas, vapour or gas mixture is supplied at a rate of at least 1 standard cubic centimeter per minute (sccm) and preferably in the range of from 1 to 100 sccm.

In the case of the monomer vapour, this is suitably supplied at a rate of from 80-300 mg/minute, for example at about 120 mg per minute depending upon the nature of the monomer, whilst the voltage is applied.

Gases or vapours may be drawn or pumped into the plasma region. In particular, where a plasma chamber is used, gases or vapours may be drawn into the chamber as a result of a reduction in the pressure within the chamber, caused by use of an evacuating pump, or they may be pumped or injected into the chamber as is common in liquid handling.

Polymerisation is suitably effected using vapours of compounds, which are maintained at pressures of from 0.1 to 200 mtorr, suitably at about 80-100 mtorr.

The applied fields are suitably of power of from 0.1 to 500 W, suitably at about 100 W peak power

The fields are suitably applied from 30 seconds to 90 minutes, preferably from 5 to 60 minutes, depending upon the nature of the compound and the item being treated etc.

Suitably a plasma chamber used is of sufficient volume to accommodate multiple items.

A particularly suitable apparatus and method for producing items in accordance with the invention is described in WO2005/089961, the content of which is hereby incorporated by reference.

These conditions are particularly suitable for depositing good quality uniform coatings, in large chambers, for example in chambers where the plasma zone has a volume of greater than 500 cm³, for instance 0.5 m³ or more, such as from 0.5 m³-10 m³ and suitably at about 1 m³. The layers formed in this way have good mechanical strength.

The dimensions of the chamber will be selected so as to accommodate the particular item being treated. For instance, generally cuboid chambers may be suitable for a wide range of applications, but if necessary, elongate or rectangular chambers may be constructed or indeed cylindrical, or of any other suitable shape.

The chamber may be a sealable container, to allow for batch processes, or it may comprise inlets and outlets for the items, material or yarn, to allow it to be utilised in a continuous process. In particular in the latter case, the pressure conditions necessary for creating a plasma discharge within the chamber are maintained using high volume pumps, as is conventional for example in a device with a “whistling leak”. However it will also be possible to process certain items at atmospheric pressure, or close to, negating the need for “whistling leaks”

The average power supply of the continuous wave plasma may be greater than 10 W.

The average power supply of the continuous wave plasma may be 20-40 W.

A second aspect of the present invention provides a method for fabricating surface tethered chiroptical switches, comprising
(a) plasma deposition of a poly(glycidyl methacrylate) film on a substrate;
(b) tethering of the chiroptical molecule (S)-3-methyl-3-amino-1-(4′-cyano-4-azobenzene)pyrrolidine to the film.

The tethering may be by an aminolysis reaction of the polymer epoxide side groups of the film with the primary amine of the chiroptical molecule (S)-3-methyl-3-amino-1-(4′-cyano-4-azobenzene)pyrrolidine.

A third aspect of the present invention provides a chiroptical switch comprising:
a substrate
a layer deposited on the substrate, said layer comprising at least one functional group;
a chiro-optical molecule attached to said functional group.

The functional group may comprise an epoxide functional group. In one embodiment, the layer comprises poly(glycidyl methacrylate).

The chiro-optical molecule may comprise at least one chiral centre. The chiro-optical molecule may comprise multiple chiral centres, for example it may comprise two chiral centres. The chiro-optical molecule may comprise at least one constrained chiral centre.

The switch may constitute polymer chains bearing chromophoric functional groups with the ability to undergo (chromophore) geometrical re-alignment upon irradiation with polarized light to yield a measurable chiral anisotropy.

The switch may undergo a reversible change in supramolecular chirality upon an external stimulus.

The chiro-optical molecule may comprise an azobenzene chromophore. The chiro-optical molecule may comprise a para-substituted azobenzene chromophore derivative with electron-donor or electron-acceptor substituents such as amine, cyano or nitro groups. The chiro-optical molecule may comprise a pyrrolidine functional group. In one embodiment, the chiro-optical molecule comprises (S)-3-methyl-3-amino-1(4′-cyano-4-azobenzene)pyrrolidine.

The substrate may be selected from but not limited to the group of glass, metal, polymer, silicon, textiles, ceramics, semiconductors, or cellulosic materials.

A fourth aspect of the present invention provides use of a chiroptical switch formed by deposition of a layer on a substrate using a compound containing at least one functional group and attachment of a chiro-optical molecule to said functional group(s), as an optical device, data storage and/or nanoscale machinery.

The chiroptical switch may have a particular use within the optical device, data storage and/or nanoscale machinery, such as acting as a rewritable memory recording device or as a molecular drive.

Preferred features of the second, third and fourth aspects of the invention may be as described above in connection with the first aspect.

Throughout the description and claims of this specification, the words “comprise”, “contain”, and “constitute” and variations of the words, for example “comprising” and “comprises”, mean “including but not limited to”, and do not exclude other moieties, additives, components, integers or steps.

Throughout the description and claims of this specification, the singular encompasses the plural unless the context otherwise requires. In particular, where the indefinite article is used, the specification is to be understood as contemplating plurality as well as singularity, unless the context requires otherwise.

Other features of the present invention will become apparent from the following example. Generally speaking the invention extends to any novel one, or any novel combination, of the features disclosed in this specification (including any accompanying claims and drawings). Thus features, integers, characteristics, compounds, chemical moieties or groups described in conjunction with a particular aspect, embodiment or example of the invention are to be understood to be applicable to any other aspect, embodiment or example described herein unless incompatible therewith. Moreover unless stated otherwise, any feature disclosed herein may be replaced by an alternative feature serving the same or a similar purpose.

The present invention will now be described by way of example only and with reference to the accompanying illustrative drawings, in which:

FIG. 1 illustrates the reorientation of a 4-amino-4′-cyano substituted azobenzene chromophore through trans-cis-trans isomerisation by incident polarized light source travelling in direction (P), with perpendicular electrical field vector (E), and where the azobenzene transition moment axis lies along (M);

FIG. 2 illustrates three possible reorientation modes for photochromic polymers irradiated with polarized light: (a) no photo-reorientation; (b) selective photo-reorientation of photochromic mesogens; and (c) cooperative photo-reorientation of photochromic and non-photochromic mesogens [24]. Where the electric field vector (E) is perpendicular to the direction of light polarization (P);

FIG. 3 illustrates the electric field vectors (E) for a travelling left circularly polarized light wave;

FIG. 4 illustrates (S)-3-methyl-3-amino-1-(4′-cyano-4-azobenzene)pyrrolidine derivatised pulsed plasma deposited poly(glycidyl methacrylate) nanolayer (cuboid) with nematic smectic C* phase supramolecular layer ordering of the azobenzene chromophore mesogens (rods) driven by trans-cis-trans photoisomerization during left circularly polarized light (1-CPL) and right circularly polarized light (r-CPL) irradiation;

FIG. 5 illustrates aminolysis attachment of (S)-3-metheyl-3-amino-1-(4′-cyano-4-azobenzene)pyrrolidine chiral chromophore to pulsed plasma deposited poly(glycidyl methacrylate) nanolayer. *Indicates a chiral centre;

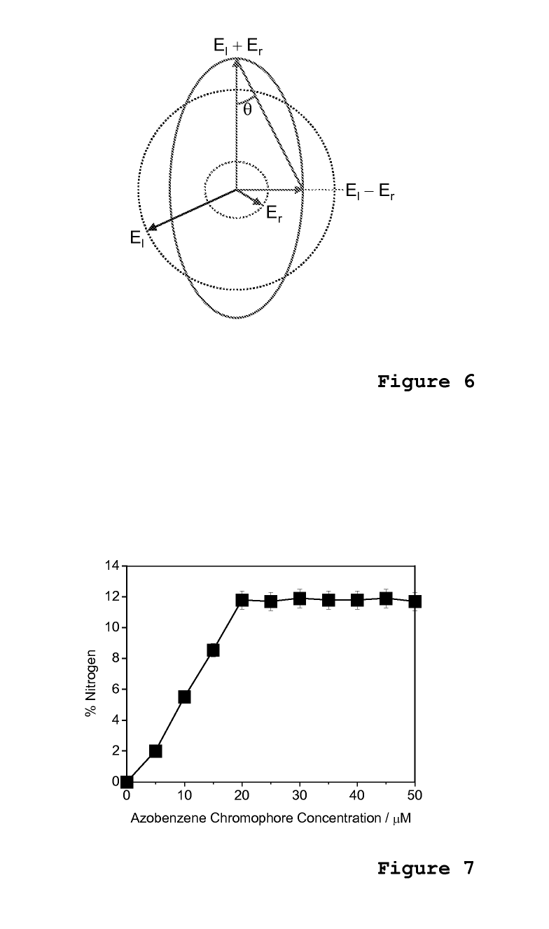

FIG. 6 illustrates elliptical polarized light (solid line) is composed of unequal contributions from electric field vectors (dotted lines) from left (Eₗ) and right (Eᵣ) circularly polarized light;

FIG. 7 illustrates XPS nitrogen concentration following aminolysis reaction of the pulsed plasma deposited poly(glycidyl methacrylate) nanofilm with (S)-3-methyl-3-amino-1-(4′-cyano-4-azobenzene)pyrrolidine as a function of dilution for 72 h immersion;

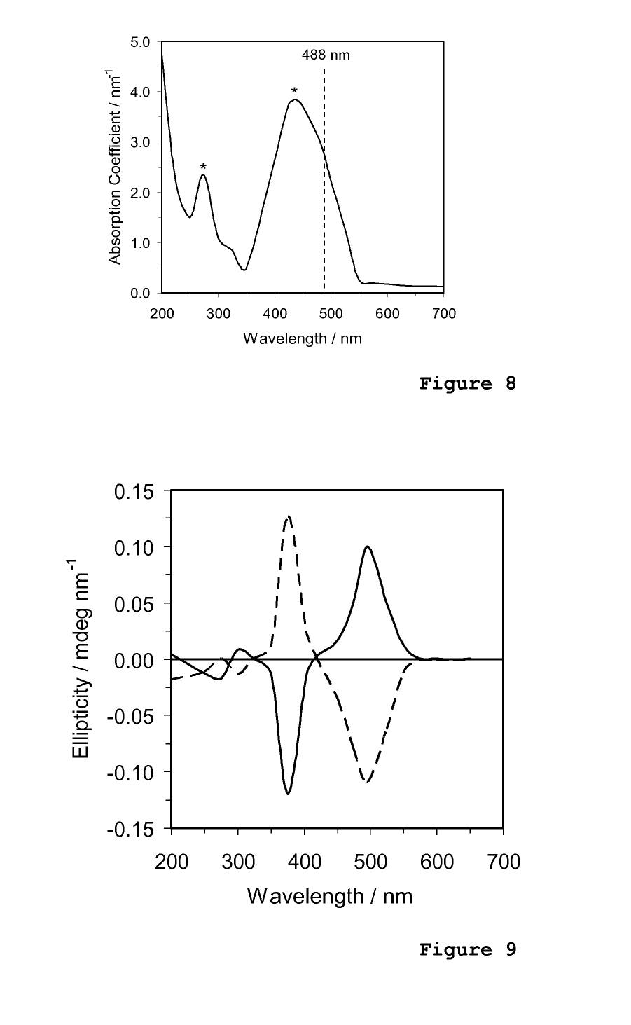

FIG. 8 illustrates UV-Vis absorption spectrum of (S)-3-methyl-3-amino-1-(4′-cyano-4-azobenzene)pyrrolidine derivatised pulsed plasma deposited poly(glycidyl methacrylate) nanofilm. *Denotes azobenzene chromophore features;

FIG. 9 illustrates circular dichroism (CD) spectra of (S)-3-methyl-3-amino-1-(4′-cyano-4-azobenzene)pyrrolidine derivatised pulsed plasma deposited poly(glycidyl methacrylate) film following a cycle of ordering using 488 nm radiation (laser intensity=50 mW cm⁻²): (a) 5 s exposure of right circularly polarized light (solid line); and (b) 5 s exposure of left circularly polarized light (dashed line); and

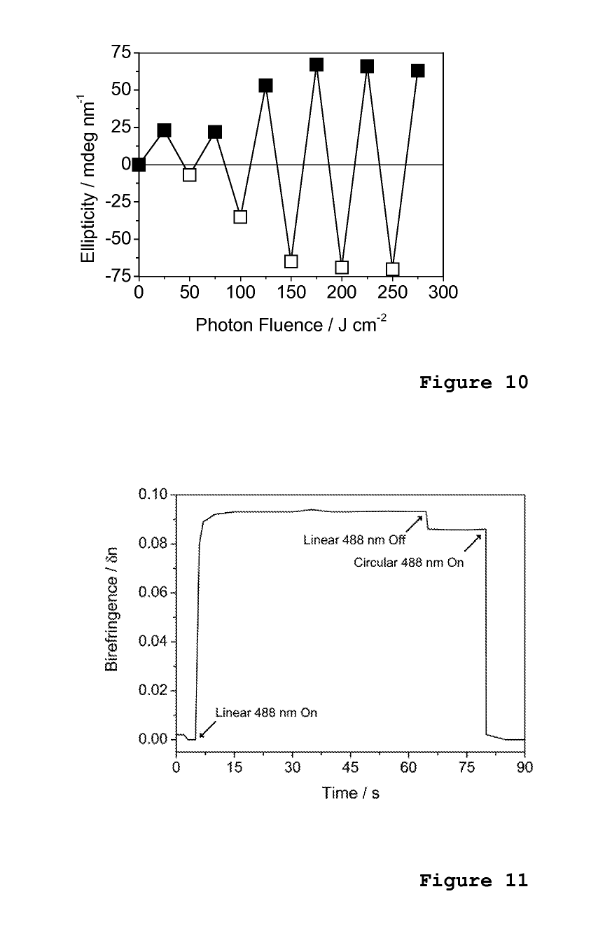

FIG. 10 illustrates the relative intensity of the circular dichroism (CD) spectra at 500 nm wavelength for a (S)-3-methyl-3-amino-1-(4′-cyano-4-azobenzene)pyrrolidine derivatised pulsed plasma deposited poly(glycidyl methacrylate) film (laser intensity—140 mW cm⁻²). Measurements correspond to the native film (photon fluence=0 J cm⁻²) and following each 180 s exposure to right circularly polarized light (black squares) and then 180 exposure to left circularly polarized light (white squares) using 488 nm radiation, as a function of the cumulative exposure (photon fluence).

FIG. 11 illustrates linear birefringence measurements of a (S)-3-methyl-3-amino-1-(40-cyano-4-azobenzene)pyrrolidine derivatized pulsed plasma poly(gylcidyl methacrylate) nanofilm monitored using cross-polarised 633 nm probe radiation. Linear polarized 488 nm pump radiation was switched on after 5 s and switched off after 65 s (the slight drop in linear birefringence after switching off can be attributed to polymer relaxation. The birefringence signal could subsequently be removed by irradiating with circularly polarized 488 nm light (switched on at 80 s).

### EXAMPLES

Pulsed plasma deposition of glycidyl methacrylate precursor (+98%, Aldrich, further purified using several freeze-pump-thaw cycles) was carried out in an electrodeless cylindrical glass reactor (5 cm diameter, 520 cm³ volume, base pressure of 1×10⁻³ mbar, and with a leak rate [56] better than 2.1×10⁻¹⁰ kg s⁻¹) enclosed in a Faraday cage. The chamber was fitted with a gas inlet, a Pirani pressure gauge, a 30 L min⁻¹ two-stage rotary pump attached to a liquid nitrogen cold trap, and an externally wound copper coil (4 mm diameter, 9 turns, spanning 8-15 cm from the gas inlet). All joints were grease free. An L-C network was used to match the output impedance of a 13.56 MHz radio frequency (RF) power generator to the partially ionised gas load. The RF power supply was triggered by a signal generator and the pulse shape monitored with an oscilloscope. Prior to each experiment, the reactor was cleaned by scrubbing with detergent, rinsing in water and propan-2-ol, followed by oven drying. The system was then reassembled and evacuated. Further cleaning entailed running an air plasma at 0.2 mbar pressure and 50 W power for 30 min. Next a fused silica slide (20 mm diameter, 0.1 mm thickness, UQG Optics Ltd) was inserted into the centre of the reactor, and the chamber pumped back down to base pressure. At this stage, glycidyl methacrylate monomer vapour was introduced at a pressure of 0.2 mbar for 5 min prior to ignition of the electrical discharge. The optimum conditions for high structural retention [45] corresponded to a peak power of 40 W, and a duty cycle on-time of 20 μs and off-time equal to 20 ms. Typical deposition rates and film thicknesses used were 15 nm min⁻¹ and 150 nm respectively.

Derivatization of the epoxide-group-containing nanofilms with the chiroptical molecule (S)-3-methyl-3-amino-1-(4′-cyano-4-azobenzene)pyrrolidine (99%, Aldrich) entailed immersion of the coated substrate into 5-50 μM dilutions in a saline sodium citrate solution (3 M sodium chloride, 0.3 M sodium citrate at pH=4.5) for 72 h. Afterwards, the samples were thoroughly rinsed in saline sodium citrate solution, high purity water, methanol, and propan-2-ol in order to remove any unreacted (S)-3-methyl-3-amino-1-(4′-cyano-4-azobenzene)pyrrolidine molecules.

Film thickness measurements were carried out using a spectrophotometer(nkd-6000, Aquila Instruments Ltd). The acquired transmittance-reflectance curves (350-1000 nm wavelength range) were fitted to a Cauchy model for dielectric materials using a modified Levenberg-Marquardt method [57].

X-ray photoelectron spectroscopy (XPS) analysis was undertaken on a VG ESCALAB MKII spectrometer. The instrument was equipped with an unmonochromated Mg Kα_{1,2} X-ray source (1253.6 eV) and a hemispherical analyser operating in the constant analyser energy mode (CAE, pass energy=20 eV). XPS core level spectra were fitted to Gaussian component peaks [58],[59] with equal full-width-at-half-maximum (fwhm) using Marquardt minimization software assuming a linear background. Elemental concentrations were calculated using experimentally derived instrument sensitivity (multiplication) factors where, C(1s):O(1s):N(1s)=1.00:0.45:0.95. The absence of any Si(2p) signal from the underlying silica substrate was taken as being indicative of pin-hole free film coverage with a thickness exceeding the XPS sampling depth (2-5 nm) [60].

UV-Vis absorption spectra of the (S)-3-methyl-3-amino-1-(4′-cyano-4-azobenzene)pyrrolidine derivatized pulsed plasma deposited poly(glycidyl methacrylate) nanofilms were measured using a UV-Vis-NIR spectrometer (Varian Carey 5) across the 200-700 nm wavelength range.

Linear dichroism and linear birefringence are related to one another by the Kramers-Kronig relationship [60A]. Linear birefringence of the (S)-3-methyl-3-amino-1-(40-cyano-4-azobenzene)pyrrolidine derivatized pulsed plasma poly(gylcidyl methacrylate) films was investigated by using a small frame Ar laser (Spectra Physics Model 165) to supply 488 nm linear polarised pump radiation and a He—Ne laser (Melles-Griot) to provide 633 nm cross-polarised probe radiation (the functional nanolayer displays negligible inherent absorption at 633 nm wavelength).

Supramolecular chiral structure in the (S)-3-methyl-3-amino-1-(4′-cyano-4-azobenzene)pyrrolidine derivatized nanofilms was induced by exposure to circular polarized light (CPL) generated by passing 488 nm radiation from a small frame Ar laser (Spectra Physics Model 165) through a multiple order λ/4 quartz waveplate.

Circular dichroism spectroscopy (CD) of the (S)-3-methyl-3-amino-1-(4′-cyano-4-azobenzene)pyrrolidine derivatized pulsed plasma deposited poly(glycidyl methacrylate) nanofilms following exposure to circularly polarized light (CPL) irradiation was recorded across the 200-650 nm wavelength range with a spectropolarimeter (Jasco J-810) transmitting a sequence of equal amounts of alternating pulses of left and right circularly polarized light at a switching rate of 50 kHz at each wavelength. The obtained spectra show the change in the molar extinction coefficient (Δ∈) for right and left-circularly polarized light as a measure of the difference in sample absorbance of the right and left-circularly polarized light as a function of wavelength after passing through the sample (due to the predominant reduction of the electric field vector (E) of one type of polarized light form over the other form). Circular dichroism spectra were recorded in degrees of ellipticity where Δθ=3298.2 Δ∈, and tan θ=(Eₗ−Eᵣ)/(Eₗ+Eᵣ), FIG. 6.

### Results

Following derivatization of the pulsed plasma deposited poly (glycidyl methacrylate) nanolayer with (S)-3-methyl-3-amino-1-(40-cyano-4-azobenzene)pyrrolidine, the film thickness was found to have increased from 150 nm thick to 290 nm. This can be taken as being indicative of the aminolysis reaction occurring throughout the film depth, FIG. 5.

XPS analysis of pulsed plasma deposited poly(glycidyl methacrylate) nanolayers indicated a good correlation to the calculated theoretical atomic percentages for the precursor, thereby indicating good structural retention [45], Table 1. Exposure of these epoxide functionalized surfaces to (S)-3-methyl-3-amino-1-(4′-cyano-4-azobenzene)pyrrolidine solution gave rise to the appearance of a N(1s) peak at 398.0 eV, which is indicative of nucleophilic attack at the epoxide centres by the amine group of the chiroptical molecule during the aminolysis reaction [45],[60], FIG. 5. For a fixed immersion period of 72 h, the level of surface derivatization (% N) was found to correlate to the dilution of (S)-3-methyl-3-amino-1-(4′-cyano-4-azobenzene)pyrrolidine solution, FIG. 7. Concentrations exceeding 20 μM yielded maximum levels of reaction with the surface epoxide groups, FIG. 7 and Table 1.

TABLE 1
XPS atomic percentages for (S)-3-methyl-3-amino-1-(4′-cyano-
4-azobenzene)pyrrolidine derivatized pulsed plasma deposited
poly(glycidyl methacrylate) nanofilms.

| | Elemental Composition | | |
|---|---|---|---|
| Sample | % C | % O | % N |
| Theoretical glycidyl methacrylate | 70.0 | 30.0 | — |
| precursor | | | |
| Pulsed plasma poly(glycidyl | 70.6 ± 0.1 | 29.4 ± 0.1 | — |
| methacrylate) | | | |
| Theoretical glycidyl methacrylate + | 75.7 | 9.1 | 15.2 |
| azobenzene chromophore | | | |
| Pulsed plasma poly(glycidyl | 78.9 ± 0.1 | 9.3 ± 0.1 | 11.8 ± 0.5 |
| methacrylate) + azobenzene | | | |
| chromophore (20 μM) | | | |

UV-Vis absorption spectroscopy was utilised to examine the optical properties of the (S)-3-methyl-3-amino-1-(4′-cyano-4-azobenzene)pyrrolidine derivatised poly(glycidyl methacrylate) films, FIG. 8. The absorption edge observed between 200 and 250 nm pertains to electronic transitions stemming from the polymer backbone and the methacrylate ester groups [61]. The azobenzene chromophore is evident by the two intense absorbances centered at 273 nm (π→π* electronic transitions of the individual aromatic rings) and 437 nm (combination band from the n→π*, first π→π*, and intramolecular charge-transfer electronic transitions) [62].

The optical behaviour of the functional nanolayers was demonstrated by measuring linear birefringence of the (S)-3-methyl-3-amino-1-(40-cyano-4-azobenzene)pyrrolidine derivatized pulsed plasma poly(gylcidyl methacrylate) films using 488 nm linear polarised pump radiation and 633 nm cross-polarised probe radiation. The initial linear birefringence value of zero confirms that the functional nanolayers are isotropic, FIG. 11. Exposure of the 488 nm linear polarized pump radiation gives rise to photoinduced linear birefringence for the 633 nm crosspolarised probe radiation (δₙ=0.092 after 10 s exposure to 488 nm linear polarized radiation), FIG. 11. Such photoinduced linear birefringence is consistent with earlier reported studies for azobenzene-containing polymer thin films [69], [63], [63A] and attributable to the re-ordering of azobenzene groups along the electric field vector direction of the pump polarized light to yield differences in absorptive behaviour between the two orientations of the crosspolarised probe radiation (i.e. linear dichroism), FIG. 2. The birefringence signal could be subsequently removed by irradiating with circularly polarized 488 nm light. This drop in linear birefringence to zero upon exposure to circularly polarized light indicates that the films are isotropic and that there is no preferred orientation of the mesogens with respect to the sample plane because the circular polarized light causes the mesogens to become helically oriented through the nanolayer (i.e. no preferred orientation within the film plane),[69] FIG. 4.

The supramolecular chiroptical behaviour of (S)-3-methyl-3-amino-1-(4′-cyano-4-azobenzene)pyrrolidine derivatized poly(glycidyl methacrylate) films was examined by circular dichroism spectroscopy (CD) following 5 s exposure to either right circularly polarized light (r-CPL) or left circularly polarized light (1-CPL) at 488 nm wavelength, FIG. 9. The circular dichroism spectra are characterized by two oppositely intense peaks at 375 nm and 488 nm [63], with a crossover point of 433 nm (which correlates to the UV-Vis absorption at 437 nm observed in FIG. 8). These features can be attributed to the azobenzene chromophore exhibiting a split circular dichroism Cotton effect [64],[65],[66], i.e. the azobenzene chromophore mesogens reaching asymmetry during exposure to left or right circularly polarized light. In the case of left circularly polarized light (1-CPL), a negative Cotton effect occurs for the azobenzene electronic transitions (identified by the ellipticity signal changing from positive to negative on going towards longer wavelengths). According to the chiral exciton coupling rules [67],[68] this is indicative of left-handed screw close packed azobenzene chromophore mesogens (a left-handed supramolecular helical arrangement of the azobenzene chromophore mesogens through the film). In the case of right circularly polarized light (r-CPL) exposure, the reverse circular dichroism signals are measured (i.e. positive Cotton effect) confirming the formation of a right-handed helical arrangement of the close packed azobenzene chromophore mesogens through the film [69]. A control sample where the (S)-3-methyl-3-amino-1-(4′-cyano-4-azobenzene)pyrrolidine derivatized poly(glycidyl methacrylate) film was examined by circular dichroism spectroscopy prior to exposure to either form of circularly polarized light, resulted in a spectral trace following the exact shape (but with greatly reduced intensity, i.e. a maximum ellipticity θ=0.03 mdeg nm-1 at a wavelength of 488 nm for the native film) as seen for the (S)-3-methyl-3-amino-1-(4′-cyano-4-azobenzene)pyrrolidine derivatized poly(glycidyl methacrylate) film which had been exposed to right circularly polarized light (therefore a slight positive Cotton effect for the azobenzene mesogen in the native film). Such chiroptical behaviour confirmed an intrinsic preference for right-handed helical ordering of the azobenzene chromophore within the native film. Furthermore, the untethered (S)-3-methyl-3-amino-1-(40-cyano-4-azobenzene)pyrrolidine molecule did not display the aforementioned behaviour. Cooperative photo-reorientation (i.e. non-chromophore polymer backbone mesogen alignment) [24] for these derivatized plasmachemical films was determined by toggling of the Cotton effect (i.e. positive to negative/negative to positive) for the circular dichroism aromatic ring π−π* transitions (crossover point at 270 nm) and the methacrylate group (crossover point at 247 nm) as a consequence of changing the handedness of the incident circularly polarized light, FIG. 9. Chiroptical “toggling” behavior was demonstrated by measuring the elliptical absolute intensity of the circular dichroism spectra at 500 nm wavelength following each step during a sequence comprising eleven alternating 180 s duration light exposure periods switching between right circularly polarized light (r-CPL) and left circularly polarized light (1-CPL) radiation at 488 nm wavelength, FIG. 10. Initial exposure of the native film (where photon fluence=0 J cm⁻²) to right circularly polarized light (r-CPL) gives rise to a positive response as reported earlier. Subsequent irradiation with left circularly polarized light (l-CPL) reverses the circular dichroism signals, and then reexposure to right circularly polarized light (r-CPL) radiation restores the original sign of the circular dichroism spectrum; therefore demonstrating write-erase cycles, i.e. rewritability. Furthermore, a progressive enhancement of the absolute signal intensities (a measure of the concentration of perpendicularly ordered azobenzene chromophore mesogens) occurs following each reversibility, to eventually reach a saturation plateau after 3 left circularly polarized light (l-CPL)/right circularly polarized light (r-CPL) pump cycles. The absolute intensity of the circular dichroism signal at 500 nm is found to be enhanced by at least a factor of 2 compared to the initially exposed film (at photon fluence=25 J cm⁻²). The toggled circular dichroism signals displayed no deterioration following 6 months storage. The possibility of false circular dichroism signal artefacts related to the distortion of linearly polarized light (such as linear birefringence and linear dichroism) which can occur if the measurement window is shorter than the timescale associated with molecular reorientation of the absorbing species [69A], can be excluded because any such linear distortions (dichroism and birefringence) were lost for the systems studied during exposure to circularly polarized light, FIG. 9. Furthermore, the observed supramolecular switching behaviour provides unequivocal evidence for the absence of artefacts, FIG. 10.

### Discussion

Derivatization of epoxide functionalized surfaces using nucleophilic reagents (e.g. carboxylic acids, amines, alcohols, etc.) typically proceeds via ring opening at the electrophilic carbon centres of the epoxide group [45]. In the case of (S)-3-methyl-3-amino-1-(4′-cyano-4-azobenzene)pyrrolidine, preferential reaction with the less substituted epoxide carbon atom is predicted (to yield the secondary alcohol) [45], thereby introducing two respective chiral centres, FIG. 5. The reaction yield of (S)-3-methyl-3-amino-1-(4′-cyano-4-azobenzene)pyrrolidine molecules immobilized onto the pulsed plasma poly(glycidyl methacrylate) nanolayer (as determined by XPS) was measured to be in excess of 77.6% derivatization (by comparing with the calculated theoretical value), Table 1 and FIG. 7. The strong azobenzene UV-Vis spectroscopy and circular dichroism (CD) signals are confirmative proof that the (S)-3-methyl-3-amino-1-(4′-cyano-4-azobenzene)pyrrolidine molecule is tethered to the pulsed plasma poly(glycidyl methacrylate) nanolayer, FIGS. 8 and 11.

These (S)-3-methyl-3-amino-1-(4′-cyano-4-azobenzene)pyrrolidine derivatized plasmachemical deposited nanofilms display a photoinduced orientation of a prevailing helical handedness of the polymeric macromolecules which is driven by circularly polarized light interacting with the azobenzene chromophore mesogens, FIG. 9 and FIG. 4. Mechanistically, under illumination, azobenzene chromophore mesogens undergo repeated trans-cis-trans photoisomerization cycles, the consequence of which is a series of motions of the chromophore dipole moments towards an orientation perpendicular to the polarization direction of the impinging light, whilst favouring close chromophoric proximity. This provides the possibility for azobenzene chromophore mesogen dipole moment mutual interaction, liquid crystalline type alignment, and photo-cooperative motion of the ordered polymer backbone segments (i.e. non-photochromic mesogens) at the nano (smectic) domain level [69], FIG. 9 and FIG. 2.

The observed chiroptical behaviour also provides scope for generating reversible switching between enantiomeric chiral arrangements of the supramolecular (mesogen based liquid crystalline) helix from clockwise to anticlockwise arrangement simply by reversing the “handedness” of the light, FIG. 10 and FIG. 4. In the case of previously studied achiral azobenzene containing polymers [33],[34], the induction of optical activity by circularly polarized light (CPL) irradiation has only been feasible when the azobenzene chromophore mesogens have been pre-ordered along a preferential direction by a liquid crystalline phase transition or by irradiating with linear polarized (LP) light. This has placed major limitations on their application due to the need for additional processing steps [70], annealing at elevated temperature [71], lower signal readouts (due to greater numbers of cis-trans transition disordering movements
[69],[72]), and poor durability (previous azobenzene derivatized methacrylate polymers are only stable for short periods prior to measurable thermal decay) [30],[69]. In contrast, the plasmachemical nanolayers employed in the present study are intrinsically chiral (with two chiral centres, FIG. 5), and photomodulation of chiroptical properties does not require any preliminary alignment of the azobenzene mesogens [61]. Introduction of a chiral centre in the polymer side group is shown to give rise to greater steric preference for helical configurations [30],[69] (in contrast to helical disordering reported for achiral azobenzene chromophore side groups during cis-trans transitions [7],[30]). In fact, azobenzene derivatized polymers which contain multiple or constrained chiral centres
[69] (such as pyrrolidine groups [73]) produce enduringly stable (with enhanced polymer matrix order) helical orientated segments (lasting up to several weeks [30],[69]), which is consistent with the prolonged longevity of the present azobenzene derivatized plasmachemical nanofilms (still stable after 6 months). The chiroptical supramolecular switching performance observed in this present study displays no deterioration in response and exhibits stable supramolecular configurations amenable to enantiomeric toggling [74], FIG. 10.

A major advantage of such supramolecular chiroptical switches when compared to photochromic molecular systems, is their non-destructive read-out confirmed by monitoring the circular dichroism intensity at specific wavelengths (e.g. 375 nm or 500 nm) centred on (or near to) actual peaks irrespective of the wavelengths used to trigger switching (e.g. 488 nm). In contrast, for photochromic molecular systems, there is often partial reversal or deadlock of the photochromic process used to store the information when using absorption or emission spectroscopy to monitor near the switching wavelengths.

Finally, in contrast to conventional highly disordered [75] and crosslinked [76] plasma polymer films [77], the presented azobenzene functionalized plasmachemical films are demonstrative of a well-defined extended supramolecular structure capable of reorienting large segments of azobenzene chromophore mesogens (together with the anchoring non-chromophore polymer mesogens via cooperative photoreorientation) enabling enantiomeric toggling (i.e. rewritability), FIGS. 9 and 10. This restructuring capability is the direct consequence of the intrinsic balance between polymer rigidity (which prevents the loss of initial azobenzene mesogen ordered orientation) [78] and polymer backbone flexibility (which enables efficient azobenzene mesogen reorientation following photoisomerization) [79] to produce photo-orientated liquid crystalline layers/domains throughout the plasmachemical film, FIG. 9. Furthermore, by varying the plasmachemical nanolayer composition (i.e. controlling the level of functional group retention and crosslinking extent) [45] it should be possible to further tailor the chiroptical performance to provide controlled optical sensitivity [80] and low cost fabrication [81],[82]. This plasmachemical approach provides well-adhered chiroptical nanolayers which are solvent resistant, substrate-independent, and applicable to a wide variety of geometries (i.e. 3-dimensional). All of these attributes offer great applicability to device applications such as nanovalves [83], nanomotors
[84],[85], nanoimpellers [86], nanosize logic gates [4],[87], molecular shuttles [88], and robotics [3].

### CONCLUSIONS

Chiroptical supramolecular switches have been prepared by reacting the chiral chromophore (S)-3-methyl-3-amino-1-(4′-cyano-4-azobenzene)pyrrolidine with the epoxide groups contained in pulsed plasma deposited poly(glycidyl methacrylate) nanolayers. The epoxide ring opening reaction yields an additional secondary alcohol chiral centre which helps to provide extra stability against trans-cis-trans chiroptical relaxation of the azobenzene chiral chromophore. Exposure to circular polarised light gives rise to supramolecular chiral ordering. Rewritable chiroptical toggling with inherent stabilities exceeding 6 months have been determined by circular dichroism spectroscopy (CD). Compared to existing ‘top down’ multi-step preparative methodologies entailing bulk polymer synthesis and then physical application to the substrate, this ‘bottom up’ approach benefits from direct plasmachemical deposition of the polymer backbone scaffold onto which the chromophore is subsequently attached to yield surface tethered supramolecular chiroptical switches. REFERENCES
[1] Zhang, Y.; Martinez-Perdiguero, J.; Baumeister, U.; Walker, C.; Etxebarria, J.; Prehm, M.; Ortega, J.; Tschierske, C.; O'Callaghan, M. J.; Harant, A.; Handschy, M. J. Am. Chem. Soc. 2009, 131, 18386.
[2] Tsuda, K.; Dol, G. C.; Gensch, T.; Hofkens, J.; Latterini, L.; Weener, J. W.; Meijer, E. W.; De Schryver, F. C. J. Am. Chem. Soc. 2000, 122, 3445.
[3] Madden, J. D. Science 2007, 318, 1094.
[4] Angelos, S.; Yang, Y.; Khashab, N. M.; Stoddart, J. F.; Zink, J. I. J. Am. Chem. Soc. 2009, 131, 11344.
[5] Siewertsen, R.; Neumann, H.; Buchheim-Stehn, B.; Herges, R.; Nather, C.; Renth, F.; Temps, F. J. Am. Chem. Soc. 2009, 131, 15594.
[6] Betancourt, J. E.; Martin-Hidalgo, M.; Gubala, V.; Rivera, J. M. J. Am. Chem. Soc. 2009, 131, 3186.
[7] Koshima, H.; Ojima, N.; Uchimoto, H. J. Am. Chem. Soc. 2009, 13, 6890.
[8] Goodman, M.; Kossoy, A. J. Am. Chem. Soc. 1966, 88, 5010.
[9] Goodman, M.; Falxa, M. L. J. Am. Chem. Soc. 1967, 89, 3863.
[10] Goodman, M.; Benedetti, E. Biochemistry 1968, 7, 4226.
[11] Todorov, T.; Niklova, L.; Tomova, N. Appl. Opt. 1984, 23, 4309.
[12] Cojocariu, C.; Rochon, P. Pure Appl. Chem. 2004, 76, 1479.
[13] El Halabieh, R. H.; Mermut, 0.; Barrett, C. J.; Pure Appl. Chem. 2004, 76, 1445.
[14] Burland, D. M.; Miller, R. D.; Walsh, C. A. Chem. Rev. 1994, 94, 31.
[15] Naito, T.; Horie, K.; Mita, I. Polym. J. 1991, 23, 809.
[16] Fujimaki, M.; Kawahara, S.; Matsuzawa, T.; Kurita, E.; Hayashi, Y.; Ichimura, K. Langmuir 1998, 14, 4495.
[17] Serak, S. V.; Tabiryan, N. V.; White, T. J.; Bunning, T. J. Opt. Express 2009, 17, 15736.
[18] Pace, G.; Ferri, V.; Grave, C.; Elbing, M.; von Hänisch, C.; Zharnikov, M.; Mayor, M.; Rampi, M. A.; Samorl, P. Proc. Natl. Acad. Sci. U.S.A. 2007, 104, 9937.
[19] Jones, R.; Tredgold, R. H.; Hoorfar, A.; Allen, R. A.; Hodge, P. Thin Solid Films 1985, 134, 57. 25/06/11 15:26:00 21
[20] Seki, T.; Kojima, J.; Ichimura, K. Macromolecules 2000, 33, 2709.
[21] Gibbons, W. M.; Shannon, P. J.; Sun, S.-T.; Swetlin, B. J. Nature 1991, 351, 49.
[22] Usami, K.; Sakamoto, K.; Tamura, N.; Sugimura, A. Thin Solid Films 2009, 518, 729.
[23] Sévigny, S.; Bouchard, L.; Motallebi, S.; Zhao, Y. Macromolecules 2003, 36, 9033.
[24] Ichimura, K. Chem. Rev. 2000, 100, 1847.
[25] Fabbri, F.; Lassailly, Y.; Lahlil, K.; Boilot, J. P.; Peretti, J. Appl. Phys. Lett. 2010, 96, 081908.
[26] Sobolewska, A.; Bartkiewicz, S.; Miniewicz, A.; Schab-Balcerzak, E. J. Phys. Chem. B 2010, 114, 9751.
[27] Lustig, S. R.; Everlof, G. J.; Jaycox, G. D. Macromolecules 2001, 34, 2364.
[28] Kim, M.-J.; Shin, B.-J.; Kim, J.-J.; Kim, D.-Y. J. Am. Chem. Soc. 2002, 124, 3504.
[29] Reigada, R.; Abad, E.; Crusats, J.; Claret, J.; Ignés-Mullol, J.; Sagués, F. J. Chem. Phys. 2004, 121, 9066.
[30] Fering a, B. L.; van Delden, R. A.; Koumura, N.; Geertsema,
E. M. Chem. Rev. 2000, 100, 1789.
[31] Okano, K.; Tsutsumi, O.; Shishido, A.; Ikeda, T. J. Am. Chem. Soc. 2006, 128, 15368.
[32] Furumi, S.; Akiyama, H.; Morino, S.; Ichimura, K. J. Mater. Chem. 1998, 8, 65.
[33] Li, Y.; He, Y.; Tong, X.; Wang, X. J. Am. Chem. Soc. 2005, 127, 2402.
[34] Kang, H.; Evmenenko, G.; Dutta, P.; Clays, K.; Song, K.;
Marks, T. J. J. Am. Chem. Soc. 2006, 128, 6194.
[35] Peng, X.; Jin, J.; Ericsson, E. M.; Ichinose, I. J. Am. Chem. Soc. 2007, 129, 8625.
[36] Kang, H.; Zhu, P.; Yang, Y.; Facchetti, A.; Marks, T. J. J. Am. Chem. Soc. 2004, 126, 15974.
[37] McCarty, L. S.; Winkleman, A.; Whitesides, G. M. J. Am. Chem. Soc. 2007, 129, 4075.
[38] Kim, J. H.; Seo, M.; Kim, Y. J.; Kim, S. Y. Langmuir 2009, 25, 1761.
[39] Garah, M. E.; Palmino, F.; Chemoux, F. Langmuir 2010, 26, 943.
[40] Levy, N.; Comstock, M. J.; Cho, J.; Berbil-Bautista, L.; Kirakosian, A.; Lauterwasser, F.; Poulsen, D. A.; Frechet, J. M. J.; Crommie, M. F. Nano Lett. 2009, 9, 935.
[41] Mielke, J.; Leyssner, F.; Koch, M.; Meyer, S.; Luo, Y.; Selvanathan, S.; Haag, R.; Tegeder, P.; Grill, L. ACS Nano 2011, 5, 2090.
[42] Bhatt, N.; Huang, P. J.; Dave, N.; Liu, J. Langmuir 2011, 27, 6132.
[43] Weidner, T.; Bretthauer, F.; Ballav, N.; Motschmann, H.; Orendi, H.; Bruhn, C.; Siemeling, U.; Zharnikov, M. Langmuir 2008, 24, 11691.
[44] Hou, X.; Sun, L.; Zhou, B.; Wu, L. Mater. Lett. 2004, 58, 369.
[45] Tarducci, C.; Kinmond, E. J.; Brewer, S. A.; Willis, C.;
Badyal, J. P. S. Chem. Mater. 2000, 12, 1884.
[46] Ryan, M. E.; Hynes, A. M.; Badyal, J. P. S. Chem. Mater.
1996, 8, 37.
[46A] E. J. Kinmond, S. R. Coulson, S. A. Brewer, C. Willis and J. P. S. Badayal, Polymer, 2005, 46, 6829.
[47] Hutton, S. J.; Crowther, J. M.; Badyal, J. P. S. Chem. Mater. 2000, 12, 2282.
[48] Tarducci, C.; Schofield, W. C. E.; Brewer, S. A.; Willis, C.; Badyal, J. P. S. Chem. Mater. 2001, 13, 1800.
[49] Rinsch, C. L.; Chen, X. L.; Panchalingam, V.; Eberhart, R. C.; Wang, J. H.; Timmons, R. B. Langmuir 1996, 12, 2995.
[50] Tarducci, C.; Brewer, S. A.; Willis, C.; Badyal, J. P. S. Chem. Commun. 2005, 3, 406.
[51] Schofield, W. C. E.; McGettrick, J. D.; Bradley, T. J.; Badyal, J. P. S.; Przyborski, S. J. Am. Chem. Soc. 2006, 128, 2280.
[52] Harris, L. G.; Schofield, W. C. E.; Doores, K. J.; Davis, B. G.; Badyal, J. P. S. J. Am. Chem. Soc. 2009, 131, 7755.
[53] Coulson, S. R.; Woodward, I. S.; Brewer, S. A.; Willis, C.; Badyal, J. P. S. Chem. Mater. 2000, 12, 2031.
[54] Limb, S. J.; Gleason, K. K.; Edell, D. J.; Gleason, E. F. J. Vac. Sci. Technol., A 1997, 15, 1814.
[55] Wang, J. H.; Chen, J. J.; Timmons, R. B. Chem. Mater. 1996, 8, 2212.
[56] Ehrlick, C. D.; Bosford, J. A. J. Vac Sci. Technol., A 1992, 10, 2.
[57] Wierman, K. W.; Hilfiker, J. N.; Woollam, J. A. Phys. Rev. B: Condens. Matter Mater. Phys. 1997, 55, 3093.
[58] Evans, J. F.; Gibson, J. H.; Moulder, J. F.; Hammond, J. S.; Goretzki, H. Fresenius J. Anal. Chem. 1984, 319, 841.
[59] Conny, J. M.; Powell, C. J. Surf. Interface Anal. 2000, 29, 856.
[60] Beamson, G.; Briggs, H. High-Resolution XPS of Organic Polymers: The Scienta ESCA300 Database; John Wiley & Sons: Chichester, U.K., 1992; p 277.
[60A] T. C. Troxell and H. A. Scherga, Macromolecules, 1971, 4, 519; R. W. Christy, Am. J. Phys., 1972, 40, 1403.
[61] Angiolini, L.; Benelli, T.; Bozio, R.; Dauru, A.; Giorgini, L.; Pedron, D. Synth. Met. 2003, 139, 743.
[62] Altomare, A.; Ciardelli, F.; Ghiloni, M. S.; Solaro, R.; Tirelli, N. Macromol. Chem. Phys. 1997, 198, 1739.
[63] Angiolini, L.; Benelli, T.; Giorgini, L.; Salatelli, E.; Bozio, R.; Daurù, A.; Pedron, D. Macromolecules 2006, 39, 489.
[63A] F. L. Lagugne-Labarthet, S. Freiiberg, M. Pellerin, A. Pezolet, A. Natansohn and P. Rochon, Macromolecules, 2000, 33, 6815.
[64] Berova, N.; Gargiulo, D.; Derguini, F.; Nakanishi, K.; Harada, N.J. Am. Chem. Soc. 1993, 115, 4769.
[65] Matile, S.; Berova, N.; Nakanishi, K.; Novkova, S.; Philipova, I.; Blagoev, B. J. Am. Chem. Soc. 1995, 117, 7021.
[66] Wu, Y.; Natansohn, A.; Rochon, P. Macromolecules 2004, 37, 6801.
[67] Nakanishi, K.; Berova, N. Circular Dichroism Principles and Applications; Nakanishi, K., Berova, N., Woody, R. W., Eds.; VCH Publishers Inc.: New York, 1994; Vol. 361.
[68] Rodger, A.; Norden, B. Circular Dichroism & Linear Dichroism; Oxford University Press: London, 1997.
[69] Natansohn, A.; Rochon, P. Chem. Rev. 2002, 102, 4139.
[69A] S. C. Bjorling, R. A. Goldbeck, S. J. Milder, C. E. Randall, J. W. Lewis and D. S. Kliger, J. Phys. Chem., 1991, 95, 4685.
[70] Kumar, G. S.; Neckers, D. C. Chem. Rev. 1989, 89, 1915.
[71] Iftime, G.; Labarthet, F. L.; Natansohn, A.; Rochon, P. J. Am. Chem. Soc. 2000, 122, 12646.
[72] Tamai, N.; Miyasaka, H. Chem. Rev. 2000, 100, 1875.
[73] Angiolini, L.; Benelli, T.; Giorgini, L.; Mauriello, F.; Salatelli, E. Macromol. Chem. Phys. 2007, 208, 207.
[74] Mueller, M.; Zentel, R. Macromolecules 1994, 27, 4404.
[75] Ryan, M. E.; Hynes, A. M.; Wheale, S. H.; Badyal, J. P. S. Chem. Mater. 1996, 8, 916.
[76] Martinu [symbol] , L.; Biederman, H.; Nedbal, J. Thin Solid Films 1986, 136, 11.
[77] Yasuda, H. Plasma Polymerization; Academic Press Inc: London, 1985.
[78] Ueda, M.; Kim, H. B.; Ikeda, T.; Ichimura, K. Chem. Mater. 1992, 4, 1229.
[79] Tsutsumi, O.; Kitsunai, T.; Kanazawa, A.; Shiono, T.; Ikeda, T. Macromolecules 1998, 31, 355.
[80] van Delden, R. A.; Mecca, T.; Rosini, C.; Fering a, B. L. Chem. Eur. J. 2004, 10, 61.
[81] Nikolova, L.; Todorov, T.; Ivanov, M.; Andruzzi, F.; Hvilsted, S.; Ramanujam, P. S. Opt. Mater. 1997, 8, 255.
[82] Nakashima, H.; Fujiki, M.; Koe, J. R.; Motonaga, M. J. Am. Chem. Soc. 2001, 123, 1963.
[83] Nelson, J. C.; Saven, J. G.; Moore, J. S.; Wolynes, P. G. Science 1997, 277, 1793.
[84] Liu, R.; Zhang, Y.; Feng, P. J. Am. Chem. Soc. 2009, 131, 15128.
[85] Angelos, S.; Johansson, E.; Stoddart, J. F.; Zink, J. I. Adv. Mater. 2007, 17, 2261.
[86] Balzani, V.; Credi, A.; Venturi, M. Molecular Devices and Machines; Wiley-VCH: Weinheim, 2008.
[87] De Silva, A. P.; Gunaratne, N.; McCoy, C. P. Nature 1993, 364, 42.
[88] Hugel, T.; Holland, N. B.; Cattani, A.; Moroder, L.; Seitz, M.; Gaub, H. E. Science 2002, 296, 1103.

1. A method for fabricating surface tethered chiroptical switches that constitute polymer chains bearing chromophoric functional groups with the ability to undergo geometrical realignment upon irradiation with polarized light to yield a measurable chiral anisotropy, the method comprising:
(a) formation of a layer on a substrate by plasma deposition using a compound containing at least one functional group;
(b) attachment of a chiro-optical molecule to said functional group(s).

2. (canceled)

3. A method according to claim 1, wherein the plasma is pulsed.

4. A method according to claim 1, wherein the switch is arranged to undergoe a reversible change in supramolecular chirality upon an external stimulus.

5. A method according to claim 1, wherein the chiro-optical molecule comprises an azobenzene chromophore.

6. A method according to claim 1, wherein the chiro-optical molecule comprises a pyrrolidine functional group.

7. A method according to claim 1, wherein the chiro-optical molecule comprises (S)-3-methyl-3-amino-1 (4′-cyano-4-azobenzene)pyrrolidine.

8. (canceled)

9. A method according to claim 1, wherein the layer is formed using glycidyl methacrylate precursor.

10. A method according to claim 1, wherein the layer comprises a nanolayer having a thickness in the range of from 100-200 nm.

11. A method according to claim 1, wherein the chiro-optical molecule comprises at least one chiral centre.

12. (canceled)

13. (canceled)

14. A method according to claim 11, wherein the functional group is an epoxide group and is derivatised by the chiro-optical molecule via an aminolysis reaction.

15. A method according to claim 1, wherein the substrate is selected from the group of glass, metal, polymer, silicon, textiles, ceramics, semiconductors, or cellulosic materials.

16. A chiroptical switch constituting polymer chains bearing chromophoric functional groups with the ability to undergo geometrical re-alignment upon irradiation with polarized light to yield a measurable chiral anisotropy, the switch comprising:
a substrate
a layer plasma deposited on the substrate, said layer comprising at least one functional group;
a chiro-optical molecule attached to said functional group(s).

17. (canceled)

18. A chiroptical switch according to claim 16, wherein the layer comprises poly(glycidyl methacrylate).

19. A chiroptical switch according to claim 1, wherein the switch is arranged to undergo a reversible change in supramolecular chirality upon an external stimulus.

20. A chiroptical switch according to claim 16, wherein the chiro-optical molecule comprises an azobenzene chromophore.

21. A chiroptical switch according to claim 16, wherein the chiro-optical molecule comprises a pyrrolidine functional group.

22. A chiroptical switch according to claim 16, wherein the chiro-optical molecule comprises (S)-3-methyl-3-amino-1(4′-cyano-4-azobenzene)pyrrolidine.

23. A chiroptical switch according to claim 16, wherein the chiro-optical molecule comprises at least one chiral centre.

24. A chiroptical switch according to claim 16, wherein the attached chiro-optical molecule comprises multiple chiral centres.

25-28. (canceled)

29. An optical device, data storage device or nanoscale machinery comprising a chiroptical switch according to claim 16.
